(19) United States
(12) Patent Application Publication
(10) Pub. No.: US 2014/0077243 A1
(43) Pub. Date: Mar. 20, 2014

(54) LIGHT EMITTING DIODE LIGHT SOURCE DEVICE

(71) Applicant: ADVANCED OPTOELECTRONIC TECHNOLOGY, INC., Hsinchu Hsien (TW)

(72) Inventors: CHUNG-MIN CHANG, Hukou (TW); CHIEN-LIN CHANG-CHIEN, Hukou (TW); HSUEN-FENG HU, Hukou (TW); CHANG-WEN SUN, Hukou (TW)

(73) Assignee: ADVANCED OPTOELECTRONIC TECHNOLOGY, INC., Hsinchu Hsien (TW)

(21) Appl. No.: 13/900,554

(22) Filed: May 23, 2013

(30) Foreign Application Priority Data
Sep. 14, 2012 (CN) 2012103384752

(51) Int. Cl. H01L 33/60

(52) U.S. Cl. CPC H01L 33/60
USPC 257/98

(57) ABSTRACT

An LED light source device includes an LED light source and a reflective layer located on a forward direction of light path of the LED light source. The LED light source includes a substrate with a first electrode and a second electrode, an LED chip and an encapsulation layer sealing the LED chip therein. The LED chip is electrically connected to the first electrode and the second electrode, respectively. The reflective layer receives part of the light emitted from the LED light source, and guides the part light to a lateral direction of the LED light source.

### BACKGROUND

1. Technical Field

The present disclosure relates to light emitting diode (LED) light source devices, and particularly to an LED light source having increased light output in lateral direction.

2. Description of Related Art

LEDs have been widely promoted as light sources of electronic devices owing to many advantages, such as high luminosity, low operational voltage and low power consumption. However, a viewing angle of light generated by the LED is 90° to 120° (±45° to ±60°) which causes the light to be too intensive at the forward direction and too weak at the lateral direction, whereby the LED is not suitable for use in illumination.

Therefore, an LED light source device which is capable of overcoming the above described shortcomings is desired.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, cross sectional view of an LED light source device in accordance with a first embodiment of the present disclosure.

FIG. 2 is a schematic, cross sectional view of an LED light source device in accordance with a second embodiment of the present disclosure.

FIG. 3 is a schematic, cross sectional view of an LED light source device in accordance with a third embodiment of the present disclosure.

FIG. 4 is a schematic, cross sectional view of an LED light source device in accordance with a fourth embodiment of the present disclosure.

### DETAILED DESCRIPTION

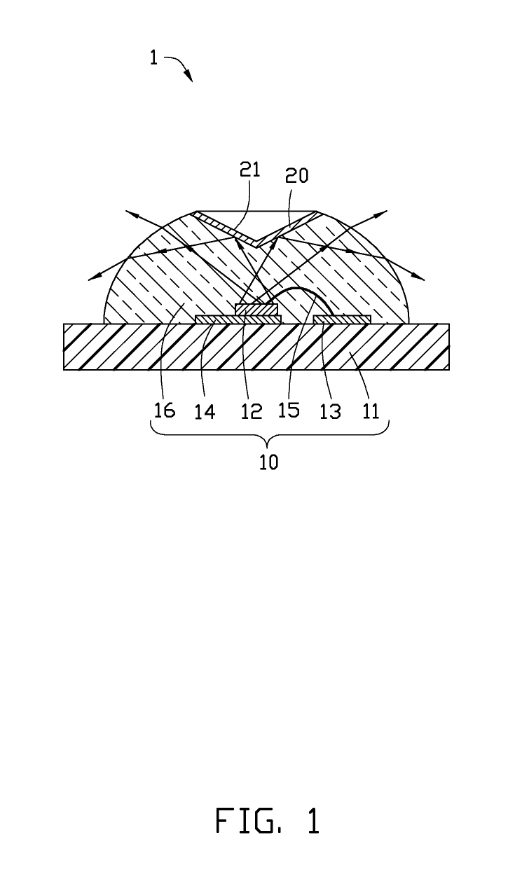

Referring to FIG. 1, an LED light source device 1 in accordance with a first embodiment of the present disclosure includes an LED light source 10 and a reflective layer 20 located on a forward direction of light path of the LED light source 10.

The LED light source 10 includes a substrate 11 with a first electrode 13 and a second electrode 14 formed thereon, an LED chip 12 and an encapsulation layer 16 sealing the LED chip 12 therein.

The LED chip 12 is electrically connected to the first electrode 13 and the second electrode 14. The first electrode 13 and the second electrode 14 are electrically connected to an external power, such as a printed circuit board, to supply power for the LED chip 12. In this embodiment, the LED chip 12 attaches to the second electrode 14, and is electrically connected to the first electrode 13 by metal wires 15. Alternatively, the LED chip 12 can be electrically connected to the first electrode 13 and the second electrode 14 by flip chip.

The encapsulation layer 16 is formed in a manner of dispensing glue, and received the LED chip 12 therein. The encapsulation layer 16 is made of transparent material with superior optical performance, such as glass, PMMA (polymethylmethacrylate) or PC (polycarbonate) plastic. A top portion of the encapsulation layer 16 defines a groove corresponding to the LED chip 12. In this embodiment, the groove is shaped to be inverted cone.

The reflective layer 20 is located in the groove of the encapsulation layer 16, and located on the forward direction of light path of the LED light source 10. The reflective layer 20 is made of opaque material with high reflecting performance, such as metal. The reflective layer 20 has a bottom surface 21, and the bottom surface 21 is attached to the bottom end of the groove. In this embodiment, a cross section of the reflective layer 20 is V-shaped, the bottom surface 21 is curved and face the LED chip 12, and a top portion of the reflective layer 20 is hollow. Alternatively, the top portion of the reflective layer 20 can be entirely filled.

During operation of the LED light source 10, light emitted from the LED light source 10 travels toward the interior of the encapsulation layer 16. A part of the light travels forwardly from the LED chip 12, and the other part of the light travels to the lateral direction of the LED chip 12. The light being sent forwardly from the LED chip 12 further travels to the reflective layer 20, and is reflected to the lateral direction of the LED chip 12 by the bottom surface 21 of the reflective layer 20, and finally travels out of the encapsulation layer 16. Therefore, the light intensity of the light emitted from the

LED light source device 1 at the lateral direction is increased.

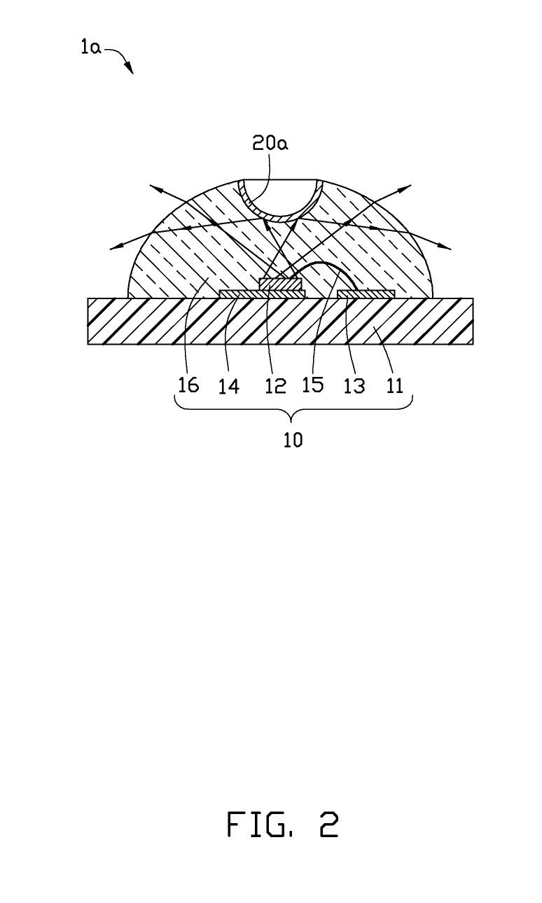

Referring to FIG. 2, an LED light source device la in accordance with a second embodiment of the present disclosure is similar to the LED light source device 1 in the first embodiment. Different from the LED light source device 1 of the first embodiment, a cross section of a reflective layer 20a of the LED light source device 1a is arc-shaped and humps towards the LED chip 12.

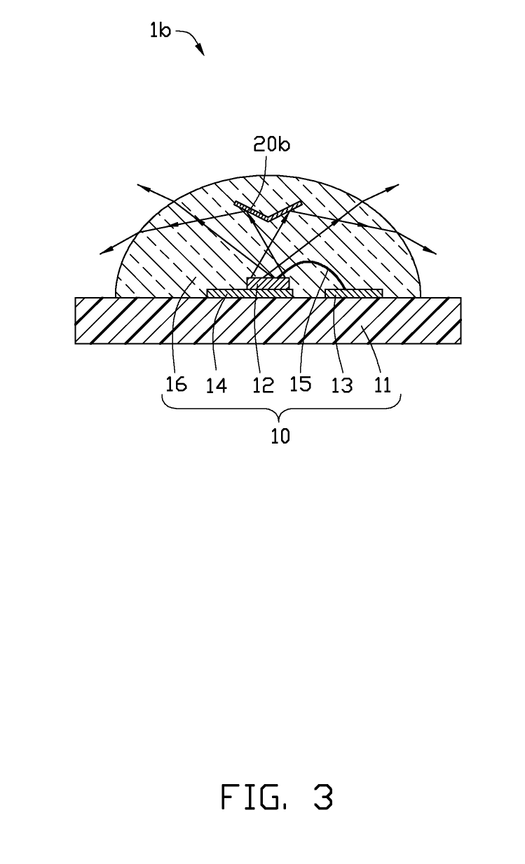

Referring to FIG. 3, an LED light source device 1b in accordance with a third embodiment of the present disclosure is similar to the LED light source device 1 in the first embodiment. Different from the LED light source device 1 of the first embodiment, a reflective layers 20b is located in the interior of the encapsulation layer 16, and the encapsulation layer 16 is hemispheric-shaped.

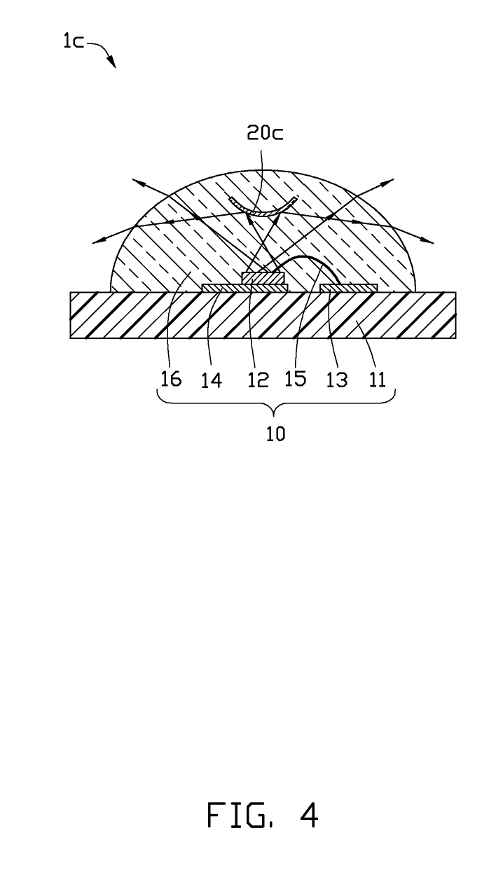

Referring to FIG. 4, an LED light source device 1c in accordance with a fourth embodiment of the present disclosure is similar to the LED light source device 1b in the third embodiment. Different from the LED light source device 1b of the third embodiment, a cross section of a reflective layer 20c of the LED light source device 1c is arc-shaped.

A particular embodiment is shown and described by way of illustration only. The principles and the features of the present disclosure may be employed in various and numerous embodiments thereof without departing from the scope of the disclosure as claimed. The above-described embodiment illustrates the scope of the disclosure but does not restrict the scope of the disclosure.

What is claimed is:

1. A light emitting diode (LED) light source device, comprising:
an LED light source comprising a substrate with a first electrode and a second electrode, an LED chip and an encapsulation layer sealing the LED chip therein, the LED chip being electrically connected to the first electrode and the second electrode, respectively;
a reflective layer located on a forward direction of light path of the LED light source;
wherein the reflective layer receives part of the light emitted from the LED light source, and guides the part light to a lateral direction of the LED light source.

2. The LED light source device of claim 1, wherein the reflective layer is made of opaque material with high reflecting performance.

3. The LED light source device of claim 2, wherein a top end of the encapsulation layer is concaved downwardly to defines a groove corresponding to the LED chip, the reflective layer is located the bottom of in the groove, and the reflective layer has a bottom surface.

4. The LED light source device of claim 3, wherein a cross section view of the reflective layer is V-shaped.

5. The LED light source device of claim 4, wherein a top end of the reflective layer is hollow.

6. The LED light source device of claim 4, wherein a top end of the reflective layer is entirely filled.

7. The LED light source device of claim 3, wherein a cross section view of the reflective layer of the LED light source is circular arc.

8. The LED light source device of claim 7, wherein a top end of the reflective layer is hollow.

9. The LED light source device of claim 7, wherein a top end of the reflective layer is entirely filled.

10. The LED light source device of claim 2, wherein the reflective layer is located the interior of the encapsulation layer, and the reflective layer has a bottom surface.

11. The LED light source device of claim 10, wherein a cross section view of the reflective layer is V-shaped.

12. The LED light source device of claim 10, wherein a cross section view of the reflective layer of the LED light source is circular arc.

13. The LED light source device of claim 1, wherein the encapsulation layer is made of transparent material.
